(19) United States
(12) Patent Application Publication
(10) Pub. No.: US 2017/0162398 A1
(43) Pub. Date: Jun. 8, 2017

(54) LOW-DAMAGE ETCHING METHOD FOR III-NITRIDE

(71) Applicant: INSTITUTE OF MICROELECTRONICS, CHINESE ACADEMY OF SCIENCES, Beijing (CN)

(72) Inventors: Xinyu LIU, Beijing (CN); Sen HUANG, Beijing (CN); Xinhua WANG, Beijing (CN); Ke WEI, Beijing (CN)

(21) Appl. No.: 15/060,406

(22) Filed: Mar. 3, 2016

(30) Foreign Application Priority Data
Dec. 2, 2015 (CN) 201510868081.1

(51) Int. Cl. H01L 21/306; H01L 29/417; H01L 29/06; H01L 21/308; H01L 29/423

(52) U.S. Cl. CPC H01L 21/30621; H01L 21/3081; H01L 29/4236; H01L 29/0649; H01L 29/41766; H01L 29/417

(57) ABSTRACT

A low-damage etching method for a III-Nitride structure is disclosed. The method comprises: forming an etching mask on the III-Nitride structure, which is formed on a substrate; and etching the III-Nitride with the etching mask, wherein a temperature of the substrate changes dynamically or is kept at a constant temperature point between 200° C. and 700° C. during the etching.

### CROSS-REFERENCE TO RELATED APPLICATION(S)

This application claims priority to Chinese Application No. 201510868081.1, entitled LOW-DAMAGE ETCHING METHOD FOR III-NITRIDE, which is incorporated herein by reference in its entirety.

### TECHNICAL FIELD

The present disclosure relates to the field of microelectronics and particularly to a low-damage etching method for a Group III nitride (III-Nitride).

### BACKGROUND

Etching techniques for a III-Nitride are key techniques in manufacturing gate recesses, pre-ohmic recesses, or mesa isolations for III-Nitride electronic devices. Conventionally, the III-Nitride etching is carried out at a room temperature, which may result in lattice damages in a III-Nitride monocrystal material. Defects and accumulation of surface etching residues are also inevitable in the room-temperature etching. Consequently, a large number of deep-levels and surface/interface states may be generated, thereby degrading dynamic performance and reliability of the devices severely.

### SUMMARY

The present disclosure provides, among other things, a low-damage etching method for a III-Nitride structure, comprising: forming an etching mask on the III-Nitride structure, which is formed on a substrate; and etching the III-Nitride with the etching mask, wherein a temperature of the substrate changes dynamically or is kept at a constant temperature point between 200° C. and 700° C. during the etching.

Optionally, during the etching, the substrate temperature may change in any one of the following ways:

the substrate temperature changes between 200° C. and 700° C.;

the substrate temperature increases linearly from 200° C. to 700° C.;

the substrate temperature increases step-wisely from 200° C. to 700° C.;

the substrate temperature increases step-wisely from 200° C. to 700° C., wherein for a corresponding time interval for each temperature step, the etching is only carried out for an early period of the time interval; or

the substrate temperature increases step-wisely from 200° C. to 700° C., wherein for a corresponding time interval for each temperature step, the etching is only carried out for a later period of the time interval.

Optionally, the III-Nitride may comprise any one selected from a group consisting of AlN, GaN, InN, or a combination of AlN, GaN, and InN.

Optionally, the etching mask may comprise a dielectric or metal material.

Optionally, the dielectric material may comprise SiO₂ or SiNₓ and the metal material may comprise any one selected from a group consisting of Ni, Ti, Pt, or TiN, or any combination thereof.

Optionally, the method according to embodiments of the present disclosure may be suitable for use in III-Nitride etching in forming a gate recess in a transistor, a pre-ohmic recess, or a mesa isolation.

Optionally, the etching may be carried out using any one selected from a group consisting of Cl-base plasma, a combination of F-base plasma and Cl-base plasma, or a combination of Ar-base plasma and Cl-base plasma.

Optionally, the Cl-base plasma may comprise any one selected from a group consisting of Cl₂, BCl₃, or a combination thereof.

Optionally, the etching may comprise inductively coupled plasma dry etching or reactive ion etching, or a combination thereof.

### BRIEF DESCRIPTION OF THE DRAWINGS

Next, detailed description will be provided with reference to accompanying drawings to facilitate thorough understanding of the present disclosure and advantages thereof, wherein:

FIG. 1 schematically shows a low-damage etching method for an III-Nitride according to an embodiment of the present disclosure;

FIGS. 2a-2e schematically show a number of ways to set a substrate temperature during the etching; and

FIG. 3 schematically shows a specific example of gate recess etching according to an embodiment of the present disclosure.

### DETAILED DESCRIPTION OF EMBODIMENTS

Other aspects, advantages, and prominent features of the present disclosure will become apparent to those skilled in the art from the following detailed description about exemplary embodiments of the present disclosure with reference to the accompanying drawings. In the present disclosure, terms “include”, “comprise”, or derivatives thereof mean “include but not be limited to.” Term “or” means and/or.

In the present disclosure, various embodiments for describing principles of the present disclosure are only illustrative and should not be interpreted to limit a scope thereof in any way. The following description with reference to the drawings facilitates a thorough understanding of the exemplary embodiments of the present disclosure defined by claims and equivalents thereof. The following description may comprise various details to facilitate the understanding. However, these details should only be deemed as illustrative. Those skilled in the art should understand that various changes and modifications may be made to the embodiments of the present disclosure without departing from a scope and spirit thereof. Moreover, well-known functions and structures are omitted for clarity and conciseness. Also, throughout the drawings, like reference numerals are used for like functions and operations.

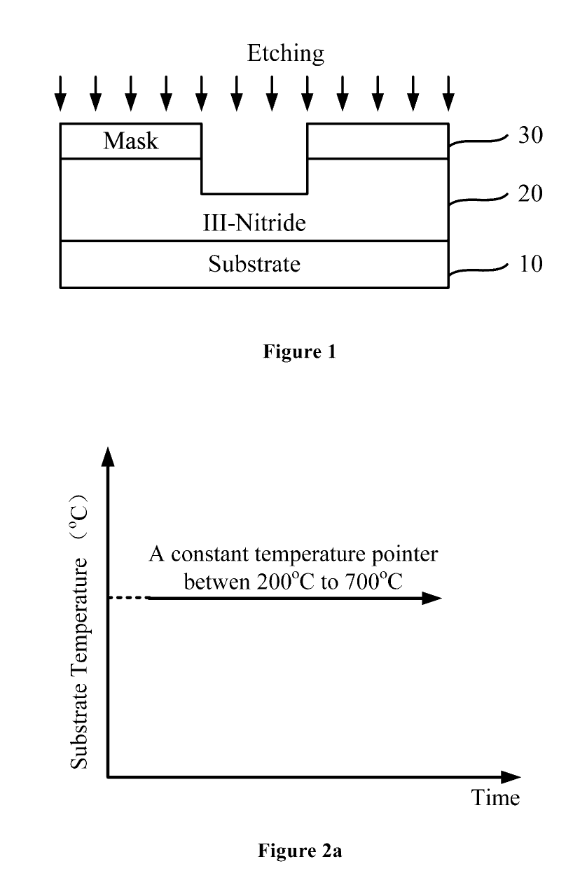

FIG. 1 schematically shows a low-damage etching method for an III-Nitride according to an embodiment of the present disclosure. As shown in FIG. 1, an III-Nitride structure 20 is formed on a substrate 10. The III-Nitride comprises any material selected from a group consisting of AlN, GaN, InN, or a combination thereof (i.e., Al(In, Ga) N). An etching mask 30 is formed on the III-Nitride structure 20. The etching mask 30 may comprise a dielectric or metal material. According to an embodiment of the present disclosure, the dielectric material may comprise SiO₂ or SiNₓ. The metal material may comprise any one selected from a group consisting of Ni, Ti, Pt, or TiN, or any combination thereof.

The III-Nitride structure 20 is etched using the etching mask 30. According to an embodiment of the present disclosure, the etching may be carried out using Cl-base plasma, a combination of F-base plasma and Cl-base plasma, or a combination of Ar-base plasma and Cl-base plasma. For example, the Cl-base plasma may comprise Cl₂ or BCl₃, or a combination thereof. The etching may comprise inductively coupled plasma dry etching or reactive ion etching, or a combination thereof.

According to an embodiment of the present disclosure, when the III-Nitride structure 20 is being etched with the etching mask 30, a temperature of the substrate 10 may be changed dynamically or be kept at a constant temperature point between 200° C. and 700° C.

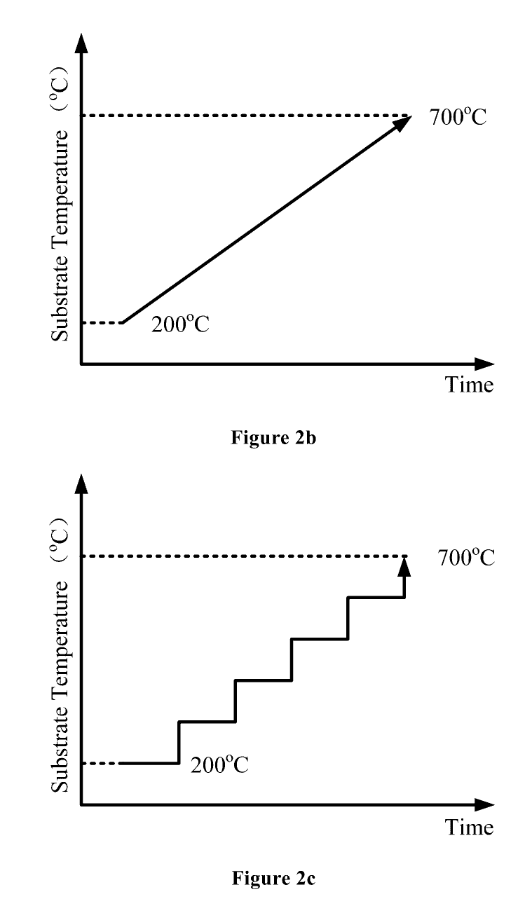

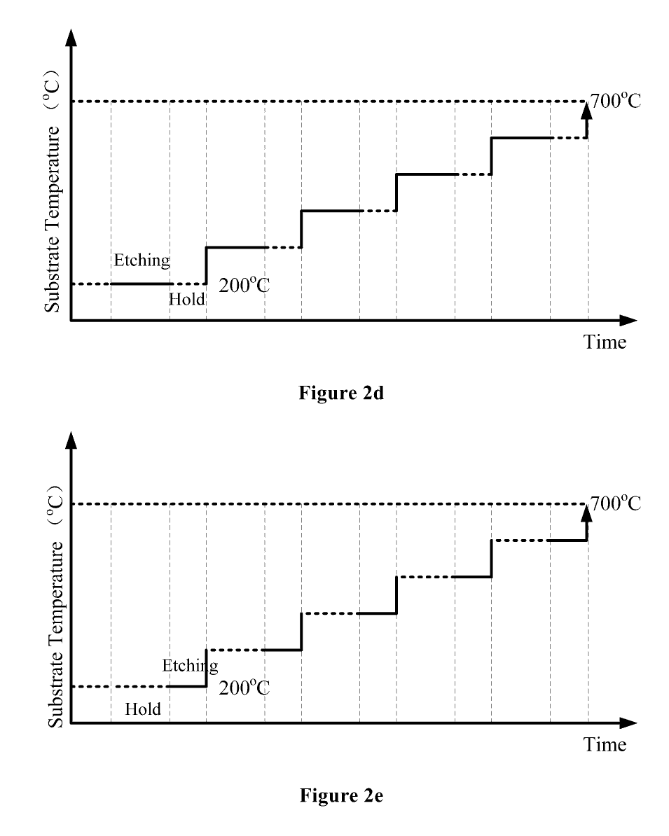

According to an embodiment of the present disclosure, the temperature of the substrate 10 may be kept at a constant temperature point (e.g., a temperature point between 200° C. and 700° C.) during the etching, as shown in FIG. 2a.

According to an embodiment of the present disclosure, the temperature of the substrate 10 may increase linearly. For example, as shown in FIG. 2b, the temperature of the substrate 10 increases linearly from 200° C. to 700° C. Linear increase of the substrate temperature may accelerate volatilization of etching residues on a surface that is being etched and in-situ reparation of lattice damages, thereby improving a profile of the surface continuously.

According to an embodiment of the present disclosure, the substrate temperature may increase step-wisely during the etching, as shown in FIG. 2c, 2d, or 2e. As shown in FIG. 2d, the temperature of the substrate 10 may increase step-wisely from 200° C. to 700° C., wherein for a corresponding time interval for each temperature step, the etching is only carried out for an early period of the time interval. As shown in FIG. 2e, the temperature of the substrate 10 may increase step-wisely from 200° C. to 700° C., wherein for a corresponding time interval for each temperature step, the etching is only carried out for a later period of the time interval. Compared to the linear increase of the substrate temperature, the step-wise increase of the substrate temperature facilitates controlling of etching rate and meanwhile provides sufficient time for the volatilization of the etching products and the reparation of the lattice damages.

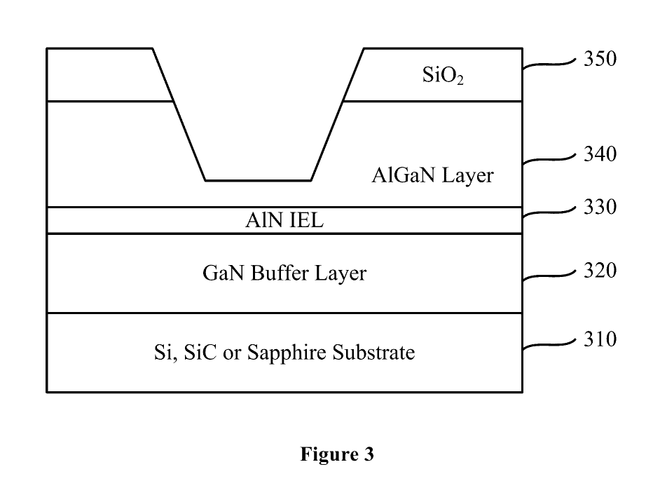

Next, the method according to an embodiment of the present disclosure will be explained in detail with reference to FIG. 3 using gate recess etching as an example. As shown in FIG. 3, an AlGaN/GaN heterojunction is formed on a sapphire substrate 310 by Metal Oxide Chemical Vapor Deposition. The AlGaN/GaN heterojunction comprises a GaN buffer layer 320 and an AlGaN barrier layer. The AlGaN barrier layer comprises an AlN interface enhancement layer (IEL) 330 and an Al_{0.25}Ga_{0.75}N layer 340. The AlN TEL 330 has a thickness of about 1 nm. The Al_{0.25}Ga_{0.75}N layer 340 has a thickness of about 21 nm. Then a SiO₂ passivation layer 350 of about 100 nm is grown at 300° C. by Plasma Enhanced Chemical Vapor Deposition (PECVD). The SiO₂ passivation layer 350 is then patterned to form an etching mask for high-temperature Cl-base (e.g., BCl₃ or Cl₂, etc.) inductively coupled plasma etching. Then the Al_{0.25}Ga_{0.75}N layer 340 is etched by ICP to a depth of about 16 nm. According to an embodiment, a temperature of the sapphire substrate 310 changes linearly between 200° C. and 700° C. during the etching. According to a further embodiment, the temperature of the sapphire substrate 310 increases step-wisely at a step of 100° C. from 200° C. to 700° C.

According to the low-damage etching method for the III-Nitride, the substrate temperature is increased so that Cl-base etching residues (e.g., AlCl₃ or GaCl₃) are removed effectively, thereby reducing roughness of the gate recess and improving surface and edge profile of the gate recess.

Furthermore, when the substrate temperature increases dynamically during the etching, volatilization of surface etching residues and in-situ annealing reparation of lattice damages caused by the etching can be accelerated, thereby the etching surface profile can be improved continuously and the lattice damages caused by the etching can be reduced effectively. In this way, the method according to the present disclosure can reduce etching damages effectively and meanwhile achieve a low static conductive resistance. Moreover, excellent enhanced threshold uniformity can be achieved, thereby improving device yield.

According to the low-damage etching method for the III-Nitride according to embodiments of the present disclosure, the substrate temperature is increased and/or changes dynamically during the etching, so that the volatilization of the surface etching residues and in-situ reparation of the lattice damages can be accelerated, thereby suppressing generation of deep levels and surface-interface states of the III-Nitride device. Consequently, dynamic performances and reliability of the device can be improved.

The method according to the present disclosure is suitable for III-Nitride etching in the gate recesses of transistors, pre-ohmic recesses, or mesa isolations in manufacture of high-performance III-Nitride microwave power devices and electronic devices.

The present disclosure has been described with reference to specific exemplary embodiments thereof. However, those skilled in the art will understand that various changes can be made with respect to formalities and details of the present disclosure without departing from the spirit and scope thereof defined by the attached claims and equivalents thereof. Therefore, the scope of the present disclosure should not be limited to the above-referenced embodiments but defined by the attached claims as well as the equivalents thereof.

1. A low-damage etching method for a III-Nitride structure, comprising:
forming an etching mask on the III-Nitride structure, which is formed on a substrate;
etching the III-Nitride with the etching mask, and
increasing a temperature of the substrate stepwisely, wherein for a time interval that corresponds to each temperature step of the substrate, the etching is restricted to a period that occurs earlier than or later than the time interval.

2. The method according to claim 1, wherein during the etching,
the substrate temperature increases step-wisely from 200° C. to 700° C.

3. The method according to claim 1, wherein the III-Nitride comprises any one selected from a group consisting of AlN, GaN, InN, or a combination of AlN, GaN, and InN.

4. The method according to claim 1, wherein the etching mask comprises a dielectric or metal material.

5. The method according to claim 4, wherein:
the dielectric material comprises SiO₂ or SiNₓ; and
the metal material comprises any one selected from a group consisting of Ni, Ti, Pt, or TiN, or any combination thereof.

6. The method according to claim 1, suitable for use in III-Nitride etching in forming a gate recess in a transistor, a pre-ohmic recess, or a mesa isolation.

7. The method according to claim 1, wherein the etching is carried out using any one selected from a group consisting of Cl-base plasma, a combination of F-base plasma and Cl-base plasma, or a combination of Ar-base plasma and Cl-base plasma.

8. The method according to claim 7, wherein the Cl-base plasma comprises any one selected from a group consisting of Cl₂, BCl₃, or a combination thereof.

9. The method according to claim 1, wherein the etching comprises inductively coupled plasma dry etching or reactive ion etching, or a combination thereof.
